(19) United States
(12) Patent Application Publication
(10) Pub. No.: US 2025/0231255 A1
(43) Pub. Date: Jul. 17, 2025

(54) DIGITAL ARCHITECTURE FOR CONTINUITY TEST

(71) Applicant: NATIONAL INSTRUMENTS CORPORATION, Austin, TX (US)

(72) Inventors: Albert Brantley Block, III, Round Rock, TX (US); Charles Thomas Yarbrough, III, Round Rock, TX (US); Kosta Ilic, Austin, TX (US); Yaoming Ren, Shanghai (CN)

(21) Appl. No.: 18/853,791

(22) PCT Filed: Apr. 29, 2022
(86) PCT No.: PCT/CN2022/090266

§ 371 Date: Oct. 3, 2024

Related U.S. Application Data
(60) Provisional application No. 63/327,693, filed on Apr. 5, 2022.

(51) Int. Cl. G01R 31/54

(52) U.S. Cl. CPC G01R 31/54

(57) ABSTRACT

Efficient continuity testing for instruments connected to a mass interconnect. Digital input and output capabilities may be used on each pin of the mass interconnect to test a variety of input/output (I/O) types on a device under test. Each pin of the interconnect may connect to a respective corresponding digital input and digital output in the tester, with the digital input resistively coupled to the digital output. The connectivity of the pin to the digital input and the digital output, and the connectivity between the digital input and the digital output may be implemented with shift registers and a buffer stage, respectively. In some embodiments, the structure may be implemented through parallel I/O blocks, as in a complex programmable logic device (CPLD), field programmable gate array (FPGA), or microcontroller.

### PRIORITY CLAIM

This application claims benefit of priority to U.S. Provisional Patent Application No. 63/327,693, titled “DIGITAL ARCHITECTURE FOR CONTINUITY TEST”, filed Apr. 5, 2022, which is hereby incorporated by reference in its entirety as though fully and completely set forth herein.

### BACKGROUND OF THE INVENTION

### Field of the Invention

This invention relates to measurement and data acquisition systems, including a test fixture used for verifying continuity between instruments positioned in a rack and a mass interconnect that connects the instruments to devices under test.

### Description of the Related Art

Measurement systems are oftentimes used to perform a variety of functions, including measurement of physical phenomena, measurement of certain characteristics or operating parameters of a unit under test (UUT) or device under test (DUT), testing and analysis of physical phenomena, process monitoring and control, control of mechanical or electrical machinery, data logging, laboratory research, and analytical chemistry, to name a few examples.

Oftentimes multiple instruments are rack mounted, or positioned in a rack that holds multiple instruments, and are individually coupled or connected to a mass interconnect from which the instruments may be coupled or connected to various devices under test or other equipment with which the instruments are intended to be used. Correct continuity between each instrument and the mass interconnect is required for the instruments to properly couple or connect to the external devices, equipment, or circuitry with which the instrument is to be used. Verifying the continuity between the instruments and the mass interconnect poses various challenges.

Other corresponding issues related to the prior art will become apparent to one skilled in the art after comparing such prior art with the present invention as described herein.

### SUMMARY OF THE INVENTION

Embodiments of systems and methods are presented herein for efficient continuity testing for instruments connected to a mass interconnect. In some embodiments, digital input and output capabilities may be used on each pin of the mass interconnect to test a variety of input/output (I/O) types on a device under test. Each pin of the interconnect may connect to a respective corresponding digital input and digital output in the tester, with the digital input and the digital output electrically coupled together, for example resistively coupled together. In some embodiments, the connectivity of the pin to the digital input and digital output and the connectivity between the digital input and digital output may be implemented with shift registers and a buffer stage. In some embodiments, the structure may be implemented through parallel I/O blocks, as in a complex programmable logic device (CPLD), field programmable gate array (FPGA), and/or microcontroller, to name a few.

Digital signals may be provided from buffers that are software reconfigurable at runtime to allow for an input or output on a particular pin. For example, for testing an analog input (AI) card, a logic low signal may be output to a negative input and a logic high signal may be output to a positive input. Then, a signal acquisition task may be run on the AI card to verify that it reads the approximate high voltage (e.g., 5V) logic level. At the same time, the pins around the AI may be set to inputs and those logic levels may be read back on a Field Diagnostic Tester (FDT) to identify adjacent shorts to other pins. The aforementioned structure allows for additional equipment to be supported in the same slot with no need for additional hardware to the FDT. Additionally, a larger (than normal) impedance may be provided to the pins, allowing the outputs to be used as weak pulls in either direction. This enables the tester to output a weak pull up to a ground pin and verify that the weak pull is actually being pulled down by the ground, which verifies the given connection (of the pin) being tested. The same slot may be reconfigured to verify an analog output card. For example, the analog output may drive a logic high voltage signal (e.g., a 5V signal) out and set the negative side logic level to low (thereby providing an isolated AO a ground reference), then read back the digital logic from the FDT to verify the pins are connected. The system may be reconfigured in real-time, e.g., through software control. The entire FDT structure may be considered a type of boundary scan with extra steps to verify that the system is wired correctly.

This Summary is intended to provide a brief overview of some of the subject matter described

in this document. Accordingly, it will be appreciated that the above-described features are merely examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

The foregoing, as well as other objects, features, and advantages of this invention may be more completely understood by reference to the following detailed description when read together with the accompanying drawings in which:

FIG. 1 shows an exemplary instrumentation control system with instruments networked together, according to some embodiments;

FIG. 2 shows a simplified circuit diagram of an exemplary measurement system architecture for continuity test using digital input and output, according to some embodiments;

FIG. 3 shows a simplified circuit diagram illustrating an exemplary continuity test system and method for a single-ended voltage input, according to some embodiments;

FIG. 4 shows a simplified circuit diagram illustrating an exemplary continuity test system and method for a differential voltage input, according to some embodiments;

FIG. 5 shows a simplified circuit diagram illustrating an exemplary continuity test system and method for a single-ended voltage output, according to some embodiments;

FIG. 6 shows a simplified circuit diagram illustrating an exemplary continuity test system and method for a differential voltage output, according to some embodiments;

FIG. 7 shows a simplified circuit diagram illustrating an exemplary continuity test system and method that uses a pulse train to drive the digital output, according to some embodiments;

FIG. 8 shows a simplified circuit diagram illustrating an exemplary continuity test system and method that uses a dedicated oscillator instead of a generic digital input/output cell, according to some embodiments; and

FIG. 9 shows a simplified circuit diagram illustrating an exemplary continuity test system and method that uses a current source to add test coverage for a cabled connection to an analog-to-digital converter, according to some embodiments.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents, and alternatives falling within the spirit and scope of the present invention as defined by the appended claims. Note, the headings are for organizational purposes only and are not meant to be used to limit or interpret the description or claims. Furthermore, note that the word “may” is used throughout this application in a permissive sense (i.e., having the potential to, being able to), not a mandatory sense (i.e., must).” The term “include”, and derivations thereof, mean “including, but not limited to”. The term “coupled” means “directly or indirectly connected”.

### DETAILED DESCRIPTION OF THE EMBODIMENTS

### Terms

The following is a glossary of terms that may appear in the present disclosure:

Memory Medium—Any of various types of non-transitory memory devices or storage devices. The term “memory medium” is intended to include an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. The memory medium may comprise other types of non-transitory memory as well or combinations thereof. In addition, the memory medium may be located in a first computer system in which the programs are executed, or may be located in a second different computer system which connects to the first computer system over a network, such as the Internet. In the latter instance, the second computer system may provide program instructions to the first computer system for execution. The term “memory medium” may include two or more memory mediums which may reside in different locations, e.g., in different computer systems that are connected over a network. The memory medium may store program instructions (e.g., embodied as computer programs) that may be executed by one or more processors.

Computer System (or Computer)—any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” may be broadly defined to encompass any device (or combination of devices) having at least one processor that executes instructions from a memory medium.

Processing Element (or Processor)—refers to various elements or combinations of elements that are capable of performing a function in a device, e.g., in a user equipment device or in a cellular network device. Processing elements may include, for example: processors and associated memory, portions or circuits of individual processor cores, entire processor cores, processor arrays, circuits such as an ASIC (Application Specific Integrated Circuit), programmable hardware elements such as a field programmable gate array (FPGA), as well any of various combinations of the above.

Configured to—Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

DUT—Device Under Test

SMU—Source Measurement Unit—an instrument that combines a sourcing function and a measurement function on the same pin or connector. An SMU may source voltage and/or current and may simultaneously measure voltage and/or current.

Resistive coupling—a coupling or connection via a resistive component/element. A resistively coupled node/component/circuit element is coupled to another node/component/circuit element via a resistor as opposed to being directly connected or coupled to the other node/component/circuit element. For example, the output of a buffer is said to be resistively coupled to a node when the output of the buffer is coupled to one end of a resistive element/component (e.g., a resistor), with the other end of the resistive element/component coupled to the node. The ends of the resistive element may be directly or indirectly coupled to the output of the buffer and/or to the node, respectively.

Various components may be described as performing a task or tasks, for convenience in the description. Such descriptions should be interpreted as including the phrase “configured to.” Reciting a component that is configured to perform one or more tasks is expressly intended not to invoke 35 U.S.C. § 112, paragraph six, interpretation for that component.

### Example Measurement/Instrument System

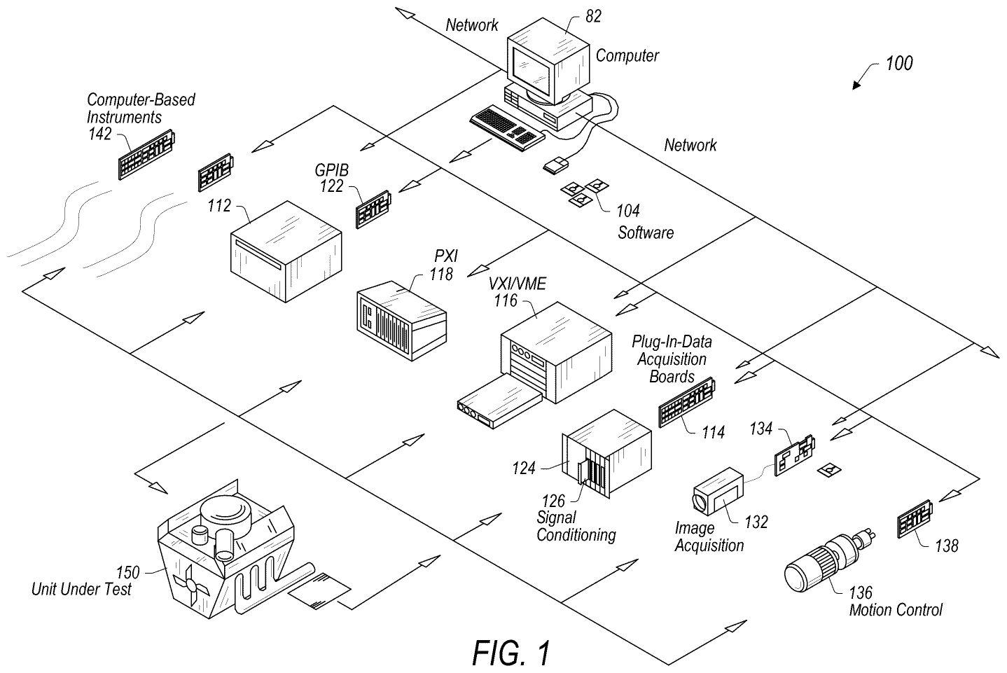

FIG. 1 illustrates an exemplary instrumentation control system 100 which may include instruments connecting or coupling to a mass interconnect according to various embodiments disclosed herein. System 100 comprises a host computer 82 which may couple to one or more instruments configured to perform a variety of functions using system level health monitoring implemented according to various embodiments of the present invention. Host computer 82 may comprise a CPU, a display screen, memory, and one or more input devices such as a mouse or keyboard as shown. Computer 82 may operate with one or more instruments to analyze, measure, or control a unit under test (UUT) or process 150. The one or more instruments may include a GPIB instrument 112 and associated GPIB interface card 122, a data acquisition board 114 inserted into or otherwise coupled with chassis 124 with associated signal conditioning circuitry 126, a VXI instrument 116, a PXI instrument 118, a video device or camera 132 and associated image acquisition (or machine vision) card 134, a motion control device 136 and associated motion control interface card 138, and/or one or more computer based instrument cards 142, among other types of devices. The computer system may couple to and operate with one or more of these instruments. In some embodiments, the computer system may be coupled to one or more of these instruments via a network connection, such as an Ethernet connection, for example, which may facilitate running a high-level synchronization protocol between the computer system and the coupled instruments. The instruments may be coupled to the unit under test (UUT) or process 150, or may be coupled to receive field signals, typically generated by transducers. System 100 may be used in a data acquisition and control applications, in a test and measurement application, an image processing or machine vision application, a process control application, a man-machine interface application, a simulation application, or a hardware-in-the-loop validation application, among others. In some embodiments, at least some components of system 100, for example, PXI instrument 118, may include multiple instruments, positioned in a rack enclosure, for example, and connected or coupled to a mass interconnect, which may in turn connect or couple the instrument to other device(s) or equipment as desired, as disclosed herein. For example, PXI instrument 118 may include some or all components of an instrument system as disclosed herein to perform various desired functions autonomously or under partial or full control of host computer 82.

### Instrument Connectivity to a Mass Interconnect

As previously mentioned, multiple instruments may be enclosed in a common enclosure or rack, and individually coupled or connected to a mass interconnect from which the instruments may be coupled or connected to various other devices, equipment, or circuitry with which the instruments may be used. Proper continuity between each instrument and the mass interconnect is required for the instruments to properly couple or connect to the external devices, equipment, or circuitry. A test fixture is typically used to verify the continuity between the instruments and the mass interconnect. The instruments are generally connected to the mass interconnect through a combination of cables and circuit card assemblies (CCAs). As is often the case, each connection point introduces a potential failure location, whether from misconnection or damage, and the failures may not be obvious, especially when the construction of the cabling and the rack is enclosed.

A Field Diagnostic Tester (FDT) is a fixture that mates/couples to the mass interconnect and provides measurement or excitation on the pins to test their continuity to the instruments inside the rack, or more generally to the instruments connected or coupled to the mass interconnect. There are a variety of FDTs, each with its respective advantages and disadvantages. In some FDTs, the continuity testing function is implemented via an STS Calibration Load Board, accomplished by providing a switching network with relays to interconnect test points, and a System DMM or System SMU to provide measurement and excitation, respectively. One particular type of FDT tester (e.g., FDT-16040 for Electronic Control Unit Test Systems, ECUTS) provides fixed loads, tailored to each instrument type connected to the pins. This allows the instrument to measure or excite the load and either the instrument or the FDT compares the response to expected results. For decades, in-circuit testers have used switching networks to route instruments to pins. Testers with programmable logic devices include logic cells on each pin that can be configured as an input and/or output. Most FDTs lack solid protection against excessive current flow in the event of an overvoltage from the connected or coupled instruments.

### Improved Connectivity Testing

In some embodiments, and improved FDT may feature a digital input and digital output tied together through resistors to a given mass interconnect pin under test. Every pin on the mass interconnect may have its own individually controlled I/O pairs. The resistors provide protection against excessive current flow in the event of an overvoltage from the instruments. Such an arrangement beneficially provides a common architecture to test continuity on a variety of different instruments and/or different types of instruments. It also allows the system to configure instruments in any order or combination rather than being limited to a subset of the fixed I/O configurations of the FDT.

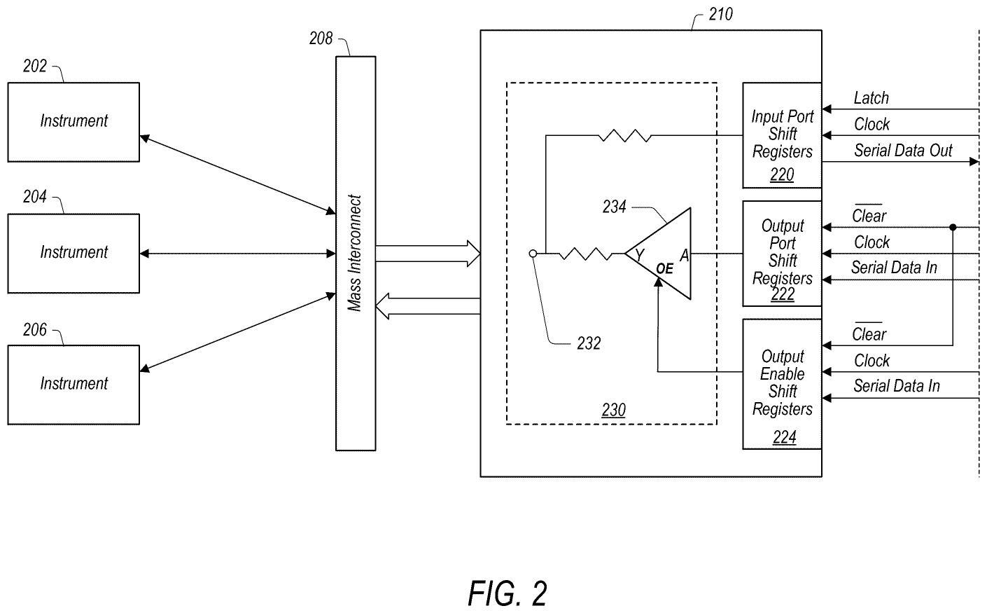

FIG. 2 shows a simplified circuit diagram of an exemplary measurement system architecture for continuity test using digital input and output. The system includes instruments 202, 204, and 206 coupled to mass interconnect 208, which couples to tester 210 (it should be noted that tester 210 may include additional components which are not shown for the sake of simplicity), which may be an FDT, for example. FIG. 2 illustrates a controlled digital I/O pair 220/222, respectively implemented with shift registers, for a single (exemplary) pin of the mass interconnect 208. The pin is represented by node 232 inside tester 210 and is coupled to a digital input port 220 of tester 210 via input shift registers, and a digital output port 222 of tester 210 via output shift registers. Serial data may be read out of input port 220 while serial data may be provided to output port 222, for example by additional circuitry or control elements of the test system. For example, in some embodiments tester 210 may be part of a test system that also includes additional components/circuitry for generating signals/data for output port 222 and reading signals/data from input port 220. As shown in the exemplary embodiment in FIG. 2, the interconnect pin, e.g., represented by node 232 inside test coupler 230, is resistively coupled to the digital input 220 and also resistively coupled to the digital output 222 via controlled buffer 234. In the illustrated embodiment, buffer 234 is controlled from output enable (shift registers) 224, to enable outputting signals/data on pin/port 232.

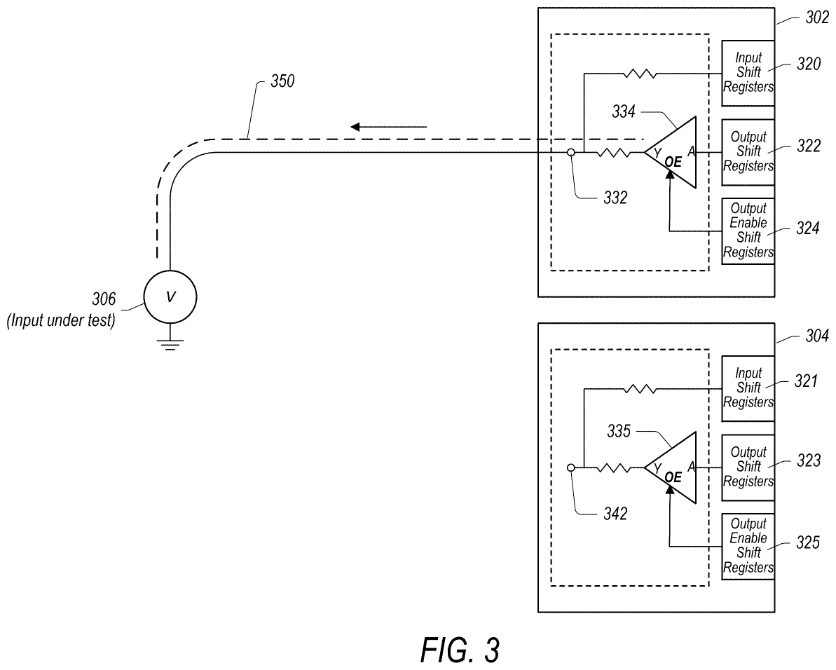

FIG. 3 shows a simplified circuit diagram illustrating an exemplary continuity test system and method for a single-ended voltage input. The embodiment shown in FIG. 3 includes two instances (302 and 304) of tester 210 used for testing connectivity of a mass interconnect pin (represented by node 332) to a respective instrument (not shown). To test instruments that measure voltage relative to system ground (such as a digital input or single-ended analog input), digital output 322 may be driven, e.g., via serial data provided to output port 322, and the voltage at the pin (represented by node 332) may be measured with the instrument, as indicated by the signal path 350 and measured voltage 306.

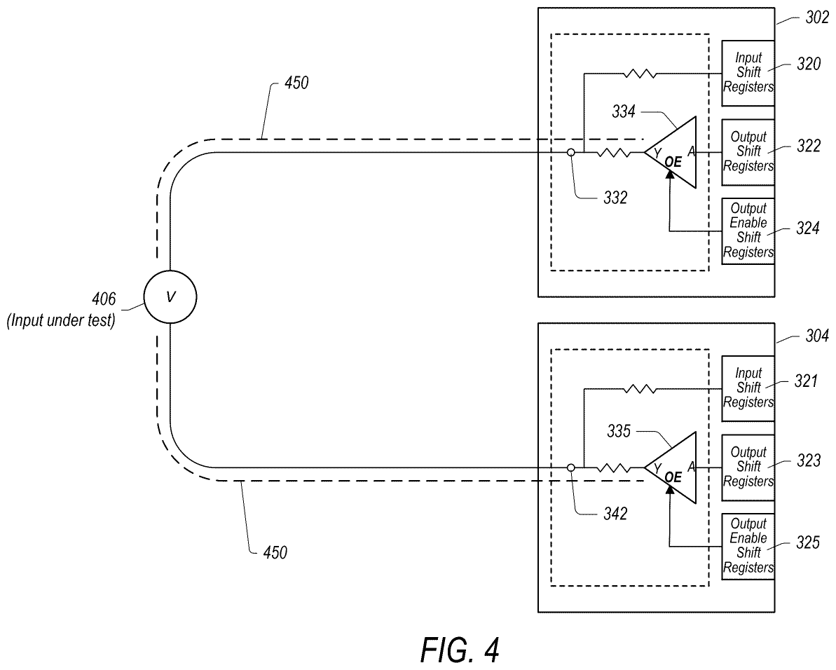

FIG. 4 shows a simplified circuit diagram illustrating an exemplary continuity test system and method for a differential voltage input. The embodiment shown in FIG. 4 includes two instances (302 and 304) of tester 210 used for testing connectivity of mass interconnect pins (represented by nodes 332 and 342) to a respective instrument (not shown). To test instruments that measure voltage between two pins, digital outputs 322 and 323 may be driven, e.g., via serial data provided to output ports 322 and 323, respectively. The instrument may then measure the relative difference in output voltage of the two pins (represented by nodes 332 and 342), as indicated by the signal path 450 and measured voltage 406. The resistor values for the resistors coupling nodes 332 and 342 to input ports 320 and 321 and buffers 334 and 335, respectively, may be selected such that the architecture may also be used to test current-input instruments.

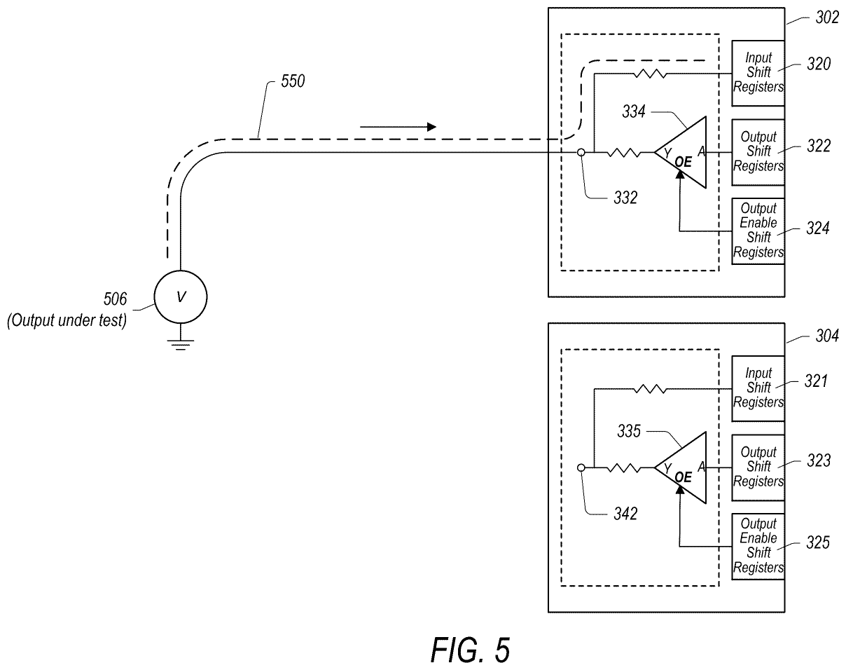

FIG. 5 shows a simplified circuit diagram illustrating an exemplary continuity test system and method for a single-ended voltage output. The embodiment shown in FIG. 5 includes two instances (302 and 304) of tester 210 used for testing connectivity of a mass interconnect pin (represented by node 332) to a respective instrument (not shown). To test instruments that generate voltage relative to the system ground, the generated voltage may be set to a valid logic level (for example, 5V) and provided to the pin (represented by node 332), and digital input 320 may be read, as indicated by the signal path 550 from generated voltage 506.

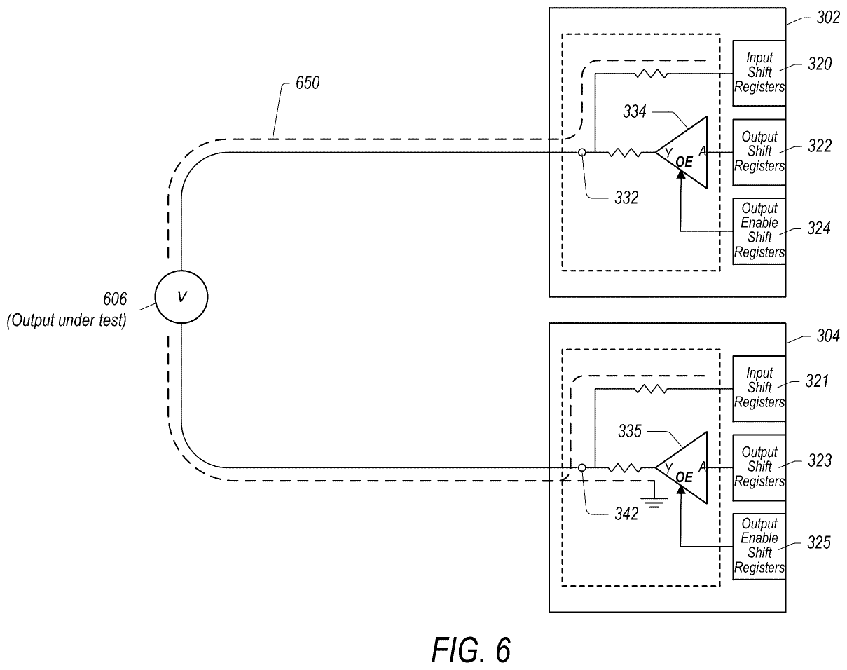

FIG. 6 shows a simplified circuit diagram illustrating an exemplary continuity test system and method for a differential voltage output. The embodiment shown in FIG. 6 includes two instances (302 and 304) of tester 210 used for testing connectivity of mass interconnect pins (represented by nodes 332 and 342) to a respective instrument (not shown). To test instruments that generate voltage between two pins that are isolated from ground, the generated voltage may be set to a valid logic level (for example, 5V), and digital output 323 may be driven to a logic low voltage while measuring for logic high on input port 320, as indicated by the signal path 650 from generated voltage 606.

In some embodiments, an alternate implementation may include a Field Programmable Gate Array (FPGA) or Complex Programmable Logic Device (CPLD) implementing the shift registers and output buffer(s). This level of integration may also save board space and reduce the number of populated components, increasing manufacturing reliability.

### Additional Embodiments

Referring again to FIG. 2, in some embodiments, latched buffers may be added on output port (shift registers) 222 and output enable (shift registers) 224 to prevent inadvertent line transitions on the DUT while loading new test vectors.

In some embodiments, to test communication buses, it may be preferable to drive or load with a similar bus. This may be accomplished with a loopback between channels. While successful communication between loopback channels implies continuity for the channels, it does not confirm that the two channels are not swapped with each other. Depending on the communication bus, various mechanisms are possible to confirm proper pinout. For buses with an input bias, such as controller area network (CAN) buses or local interconnect network (LIN) buses, the bias may be removed, causing an expected failure on the receiving side of the loopback. This may be used to confirm the proper orientation of the two channels in the loopback. For buses without a bias, such as Ethernet, a third channel may be looped in to replace one of the original pair.

It should be noted that the various embodiments presented herein are inherently modular and may be extended to multiple channels, depending on the size and type of connectivity to be tested. Certain test fixtures, e.g., such as the NI FDT-16041, include a logic controller and many of the above-mentioned logic cells. These cells may be deployed on a motherboard and multiple daughterboards, each connecting to slots of the mass interconnect under test. Daughterboards may have different configurations, and may contain identification mechanisms, such as hard-wires, identification resistors, and/or non-volatile memories. These allow for multiple configurations of the fixture to be automatically detected and used.

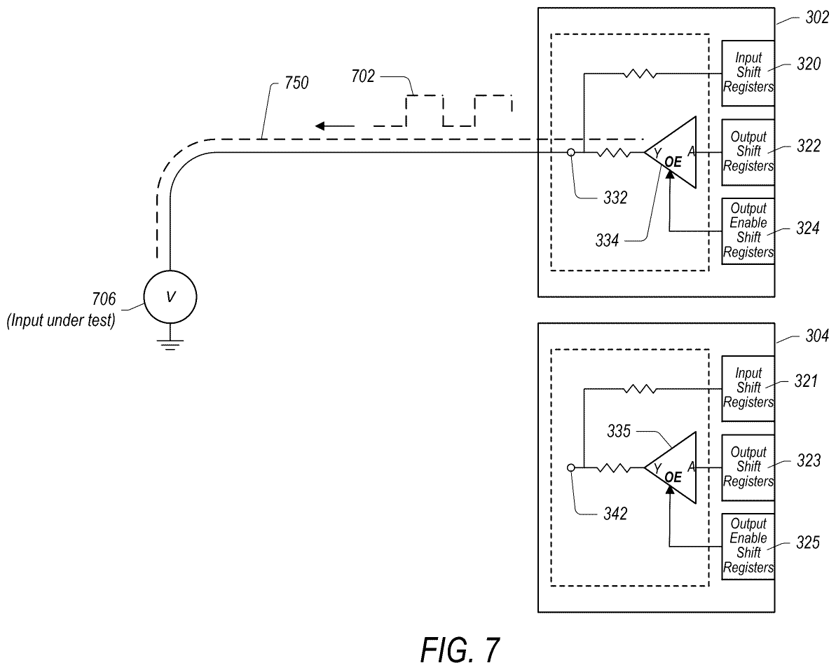

FIG. 7 shows a simplified circuit diagram illustrating an exemplary continuity test system and method that uses a pulse train to drive the digital output. The embodiment shown in FIG. 7 includes two instances (302 and 304) of tester 210 used for testing connectivity of a mass interconnect pin (represented by node 332) to a respective instrument (not shown). To test signal lines that require a transitioning signal, the digital output 322 may be driven with a pulse train 702 as shown. The device under test (measuring/detecting the signal at node 332) may recognize an edge transition, thereby confirming continuity, as indicated by the signal path 750 and measured voltage 706. Depending on the timing requirements of the device under test, the pulse train 702 may be generated by “bit-banging” using application-level software, real-time operating system (OS) software, or hardware logic.

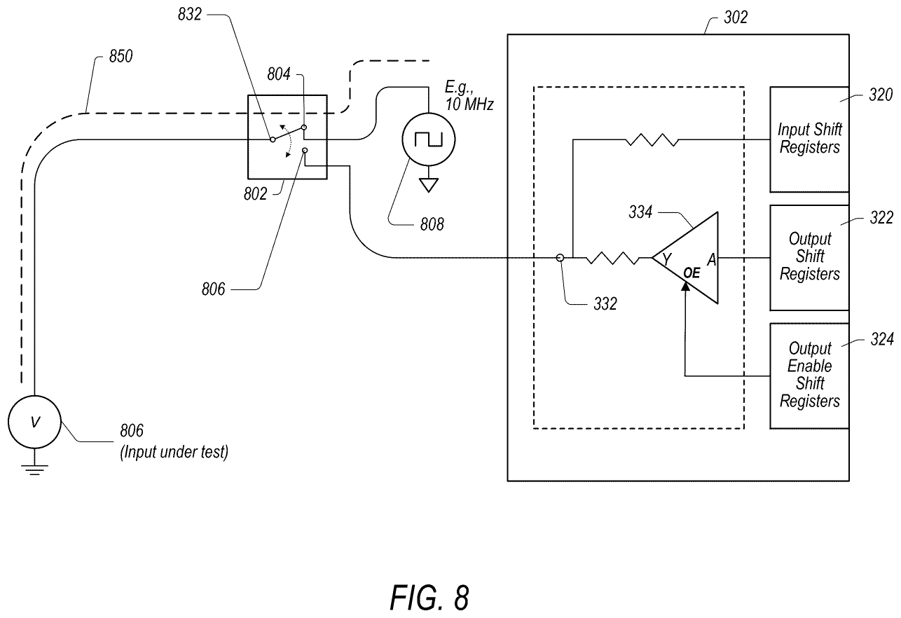

FIG. 8 shows a simplified circuit diagram illustrating an exemplary continuity test system and method that uses a dedicated oscillator instead of a generic digital input/output cell, according to some embodiments. The embodiment shown in FIG. 8 includes an instance (302) of tester 210 used for testing connectivity of a mass interconnect pin (in this instance represented by node 832) to a respective instrument (not shown). To test signal lines that require high frequency and high accuracy signals, such as a PLL (Phase-Locked Loop) input, it may be preferable to switch in a dedicated oscillator 808 instead of using the generic digital input/output cell 302. In order to maintain testing flexibility, oscillator 808 may be switchably coupled to node 832 via switch 802. Accordingly, switch 802 may be toggled to couple oscillator 808 to node 832 via switch port 804, or it may be toggled to couple I/O cell 302 (via node 332) to node 832 via switch port 806. The voltage at the pin (represented by node 832) may be measured with the instrument, as indicated by the signal path 850 and measured voltage 806. To test signal lines that require current input larger than what can be supplied by the digital output 322, a current source may be switched to pin/node 832 via switching mechanism 802 in a similar manner as oscillator 808.

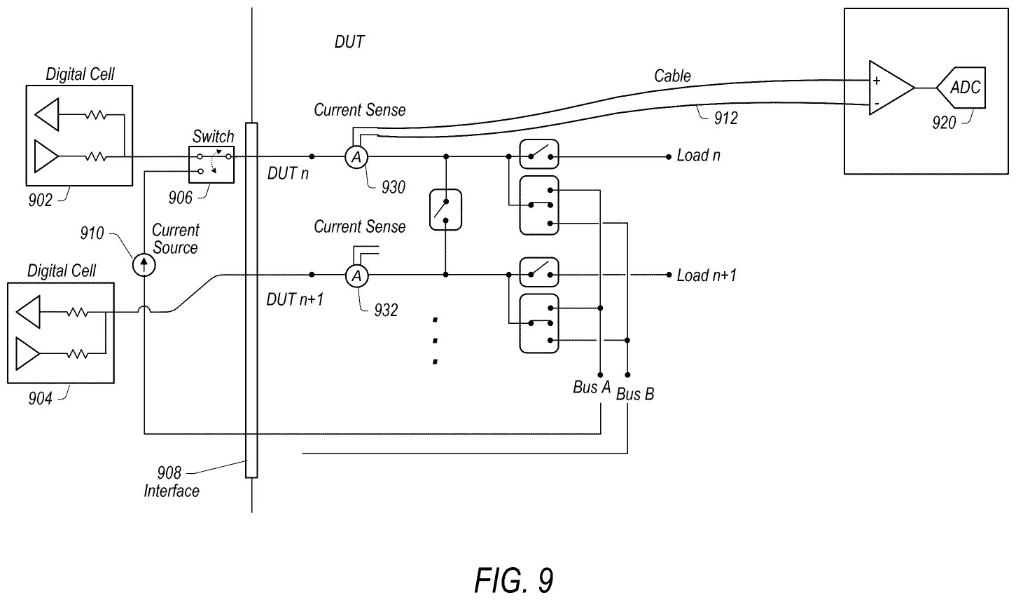

The pin continuity routines may be used individually or in combination to test proper connection and function of internal circuits, including those circuits that may not be directly coupled to the pin being tested. FIG. 9 shows a simplified circuit diagram illustrating an exemplary continuity test system and method with digital cells 902 and 904, and additionally a current source 910 to enable test coverage for a cabled connection to an analog-to-digital converter 920. In the embodiment illustrated in FIG. 9, current source 910 may be applied to a pin in switch 906 that couples to current sensor 930 in a first DUT (DUT n). The current sensor 930 may be cabled, via cable 912, to a voltage measurement device that is not otherwise externally accessible. In the specific embodiment shown in FIG. 9, the continuity measurement system and method with current source 910 enable test coverage for the cabled connection to the ADC 920.

Although the embodiments above have been described in considerable detail, other versions are possible. Numerous variations and modifications will become apparent to those skilled in the art once the above disclosure is fully appreciated. It is intended that the following claims be interpreted to embrace all such variations and modifications. Note the section headings used herein are for organizational purposes only and are not meant to limit the description provided herein or the claims attached hereto.

1. A test circuit for testing connectivity of one or more instruments to a mass interconnect, the test circuit comprising:
a connection port configured to couple to a first pin of the mass interconnect, wherein the first pin is configured to couple to a first instrument of the one or more instruments; and
an individually controlled pair of digital ports, wherein the pair of digital ports includes:
a digital input port resistively coupled to the connection port; and
a digital output port resistively coupled to the connection port.

2. The test circuit of claim 1, further comprising:
a controllable buffer having an input coupled to the digital output port, and an output resistively coupled to the connection port.

3. The test circuit of claim 2, further comprising:
an enable port configured to control the buffer to selectively drive the connection port with a stimulus signal.

4. The test circuit of claim 3, wherein the enable port comprises shift registers configured to receive serial data and control the buffer according to at least the received serial data.

5. The test circuit of claim 1, wherein the digital input port comprises input shift registers configured to output serial test data, and wherein the digital output port comprises output shift registers configured to receive serial stimulus data.

6. The test circuit of claim 5, wherein when testing a voltage output, the serial test data is generated by driving the connection port with a test signal from the first pin.

7. The test circuit of claim 5, wherein when testing a voltage input, the connection port is driven by a stimulus signal based at least on the serial stimulus data.

8. A test system comprising:
one or more instruments;
a mass interconnect coupled to the one or more instruments; and
a test circuit for testing connectivity of the one or more instruments to the mass interconnect, the test circuit comprising:
a connection port configured to couple to a first pin of the mass interconnect, wherein the first pin is configured to couple to a first instrument of the one or more instruments; and
an individually controlled pair of digital ports, wherein the pair of digital ports includes:
a digital input port resistively coupled to the connection port; and
a digital output port resistively coupled to the connection port.

9. The test system of claim 8, wherein the test circuit further comprises:
a controllable buffer having an input coupled to the digital output port, and an output resistively coupled to the connection port.

10. The test system of claim 9, wherein the test circuit further comprises:
an enable port configured to control the buffer to selectively drive the connection port with a stimulus signal.

11. The test system of claim 10, wherein the enable port comprises shift registers configured to receive serial data and control the buffer according to at least the received serial data.

12. The test system of claim 8, wherein the digital input port comprises input shift registers configured to output serial test data, and wherein the digital output port comprises output shift registers configured to receive serial stimulus data.

13. The test system of claim 12, wherein when testing a voltage output, the serial test data is generated by driving the connection port with a test signal from the first pin.

14. The test system of claim 12, wherein when testing a voltage input, the connection port is driven by a stimulus signal based at least on the serial stimulus data.

15. A test system comprising:
a mass interconnect comprising a plurality of pins configured to couple to a corresponding plurality of instruments; and
a plurality of test circuits configured to test connectivity of the plurality of instruments to the plurality of pins, wherein each test circuit of the plurality of test circuits comprises:
a connection port configured to couple to a respective pin of the plurality of pins, wherein the respective pin is configured to couple to a corresponding instrument of the plurality of instruments; and
an individually controlled pair of digital ports, wherein the pair of digital ports includes:
a digital input port resistively coupled to the connection port; and
a digital output port resistively coupled to the connection port.

16. The test system of claim 15, wherein each test circuit further comprises:
a controllable buffer having an input coupled to the digital output port, and an output resistively coupled to the connection port.

17. The test system of claim 16, wherein each test circuit further comprises:
an enable port configured to control the buffer to selectively drive the connection port with a stimulus signal.

18. The test system of claim 15, wherein the digital input port comprises input shift registers configured to output serial test data, and wherein the digital output port comprises output shift registers configured to receive serial stimulus data.

19. The test system of claim 18, wherein when testing a voltage output, the serial test data is generated by driving the connection port with a test signal from the respective pin.

20. The test system of claim 18, wherein when testing a voltage input, the connection port is driven by a stimulus signal based at least on the serial stimulus data.
